(19) United States
(12) Patent Application Publication
(10) Pub. No.: US 2026/0114064 A1
(43) Pub. Date: Apr. 23, 2026

(54) IMAGE SENSING DEVICE

(71) Applicant: SK hynix Inc., Icheon-si (KR)

(72) Inventor: Sang Jin PARK, Icheon-si (KR)

(21) Appl. No.: 19/281,377

(22) Filed: Jul. 25, 2025

(30) Foreign Application Priority Data
Oct. 22, 2024 (KR) 10-2024-0145197

(51) Int. Cl. H10F 39/00

(52) U.S. Cl. CPC H10F 39/8057; H10F 39/811; H10F 39/8063

(57) ABSTRACT

Image sensing devices are disclosed. In an embodiment, an image sensing device includes a substrate including a pixel area and a peripheral area located outside the pixel area, the peripheral area including pad regions and a first adhesion-enhancing structure located between the pixel area and the pad regions and including a plurality of protrusions and recesses; a plurality of first substrate isolation structures disposed in the substrate and surrounding each of the pad regions; and a light blocking layer disposed over the substrate and configured to cover the first adhesion-enhancing structure and the first substrate isolation structures.

### CROSS-REFERENCE TO RELATED APPLICATION

This patent document claims the priority and benefits of Korean patent application No. 10-2024-0145197, filed on Oct. 22, 2024, which is incorporated by reference in its entirety as part of the disclosure of this patent document.

### TECHNICAL FIELD

The technology and implementations disclosed in this patent document generally relate to an image sensing device.

### BACKGROUND

An image sensor can capture optical images by converting light into electrical signals using a photosensitive semiconductor material that reacts to light. With advancements in industries such as computer and communication industries, the demand for high-performance image sensors is growing across various fields such as digital cameras, camcorders, personal communication systems (PCSs), game consoles, surveillance cameras, medical micro cameras, robots, etc.

In an attempt to meet the demands for high-resolution, high-speed operation, multi-layer image sensing devices have been developed. These devices include upper layers stacked on lower layers, with through-silicon-via (TSV) structures that electrically connect the circuits between the upper and lower layers.

### SUMMARY

Various embodiments of the disclosed technology relate to an image sensing device capable of preventing peeling of a lens layer while preventing damage to substrate isolation structures surrounding a pad region.

In an embodiment of the disclosed technology, an image sensing device may include a substrate including: a pixel area configured to include image sensing pixels; and a peripheral area located outside the pixel area and configured to include pad regions and a first adhesion-enhancing structure located between the pixel area and the pad regions and including a plurality of protrusions and recesses; a plurality of first substrate isolation structures disposed in the substrate and surrounding each of the pad regions; and a light blocking layer disposed over the substrate and configured to cover the first adhesion-enhancing structure and the first substrate isolation structures.

In another embodiment of the disclosed technology, an image sensing device may include: a first stacked structure including: a pixel area configured to include image sensing pixels and a plurality of first pad regions located outside the pixel area; and a second stacked structure stacked electrically connected to the first stacked structure and configured to include a logic area configured to include logic circuits and a plurality of second pad regions located outside the logic area, wherein each second pad region includes an electrode pad. The first stacked structure may include: a substrate configured to include pad open regions formed in the first pad regions and a first adhesion-enhancing structure disposed between the pixel area and the pad open regions and including a plurality of protrusions and recesses; substrate isolation structures disposed to penetrate the substrate and configured to surround each of the first pad regions; and a light blocking layer disposed over the substrate and configured to cover the first adhesion-enhancing structure and the first substrate isolation structures.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a schematic diagram illustrating an example of an image sensing device based on some implementations of the disclosed technology.

FIG. 3 is a plan view illustrating an example of a planar arrangement of a first stacked structure in the image sensing device shown in FIG. 2 based on some implementations of the disclosed technology.

FIG. 4 is a cross-sectional view illustrating an example of a cross-section taken along the line X-X′ of FIG. 3 in the stacked structure shown in FIG. 2 based on some implementations of the disclosed technology.

FIGS. 5A to 5F are cross-sectional views illustrating examples of a method for forming the structure of FIG. 4 based on some implementations of the disclosed technology.

FIG. 6 is a cross-sectional view illustrating an example structure of an image sensing device based on some other implementations of the disclosed technology.

FIG. 7 is a cross-sectional view illustrating an example structure of an image sensing device based on some other implementations of the disclosed technology.

FIG. 8 is a cross-sectional view illustrating an example structure of an image sensing device based on some other implementations of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of an image sensing device that can prevent peeling of a lens layer while preventing damage to substrate isolation structures surrounding a pad region. In recognition of the issues above, the disclosed technology provides various implementations of the image sensing device that can prevent damage to substrate isolation structures and peeling of the lens layer, thereby improving operation characteristics of the image sensing device.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

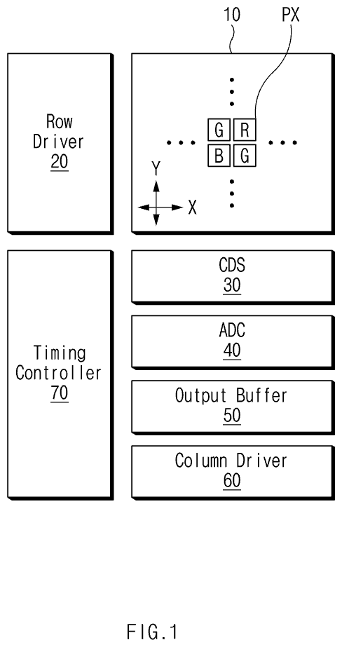

FIG. 1 is a block diagram illustrating an example of an image sensing device based on some implementations of the disclosed technology.

Referring to FIG. 1, the image sensing device may include a pixel array 10, a row driver 20, a correlated double sampler (CDS) 30, an analog-to-digital converter (ADC) 40, an output buffer 50, a column driver 60, and a timing controller 70. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel array 10 may include a plurality of unit pixels (PXs) arranged in a first direction (e.g., an X-axis direction) and a second direction (e.g., a Y-axis direction). The plurality of unit pixels may convert an optical signal into an electrical signal on a unit pixel basis or a pixel group basis. The plurality of unit pixels (PXs) may be arranged in a Bayer pattern.

The row driver 20 may activate the unit pixels (PXs) based on control signals received from controller circuitry such as the timing controller 70. The pixel signals generated by the unit pixels may be output to the correlated double sampler (CDS) 30.

The correlated double sampler (CDS) 30 may remove undesired offset values of the unit pixels using correlated double sampling. In some implementations, upon receiving a clock signal from the timing controller 70, the CDS 30 may sequentially sample and hold a voltage level of the reference signal and a voltage level of the pixel signal that is supplied from the pixel array 10 through a plurality of column lines. In some implementations, the CDS 30 may transfer the reference signal and the pixel signal as a correlate double sampling (CDS) signal to the ADC 40 based on control signals from the timing controller 70.

The ADC 40 may convert the CDS signal received from the correlated double sampler (CDS) 30 into a digital signal, and may output the digital signal to the output buffer 50.

The output buffer 50 may temporarily store column-based data received from the ADC 40 under the control of the timing controller 70.

The column driver 60 may select a column of the output buffer 50 under the control of the timing controller 70, and may sequentially output data temporarily stored in the selected column of the output buffer 50.

The timing controller 70 may generate signals for controlling the row driver 20, the ADC 40, the output buffer 50 and the column driver 60.

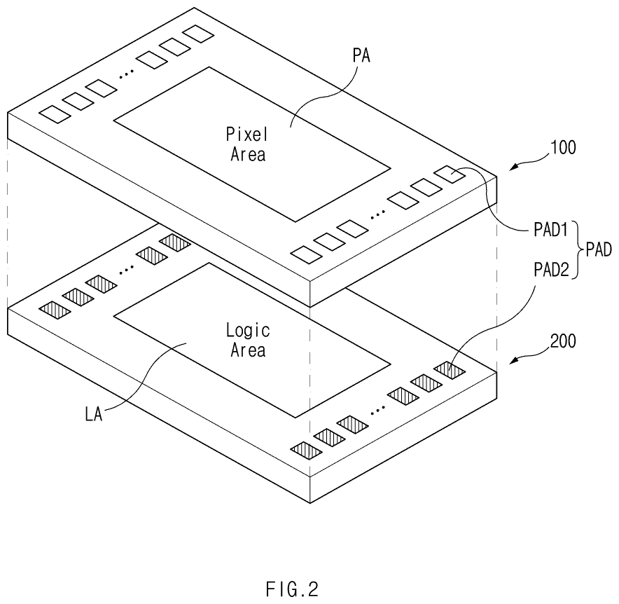

FIG. 2 is a schematic diagram illustrating an example of the image sensing device based on some implementations of the disclosed technology.

Referring to FIG. 2, the image sensing device may include a first stacked structure 100 and a second stacked structure 200.

The first stacked structure 100 and the second stacked structure 200 may be stacked to be electrically connected through a hybrid bonding (or direct bonding) structure.

The first stacked structure 100 may include a pixel area (PA) in which a pixel array 10 of FIG. 1 is formed, and a first pad region (PAD1) located in a first peripheral area surrounding the pixel area (PA). The pixel area (PA) may be disposed at a center portion of the first stacked structure 100.

The second stacked structure 200 may include a logic area (LA) and a second pad region (PAD2). The logic area (LA) may include circuitry for operating the pixel array 10 of the first stacked structure 100 and processing pixel electrical signals from the pixel array 10, including, for example, the row driver 20, the CDS 30, the ADC 40, the output buffer 50, the column driver 60, and the timing controller 70. The second pad region (PAD2) may be located in a second peripheral area surrounding the logic area (LA). The logic area (LA) may be located at a center portion of the second stacked structure 200 to correspond to the pixel area (PA).

The first pad region (PAD1) and the second pad region (PAD2) may be disposed to overlap each other in the vertical direction. The second pad region (PAD2) may include an electrode pad connected to a bonding wire, and the first pad region (PAD1) may include a pad open region for exposing the electrode pad. In some implementations, the pad region (PAD) may be formed as a direct pad structure in which the bonding wire is directly connected to the metal interconnects of the second stacked structure 200, rather than a structure in which an electrode pad is formed over the first stacked structure 100 and the electrode pad is connected to the metal interconnects of the second stacked structure 200 through a through silicon via (TSV) structure.

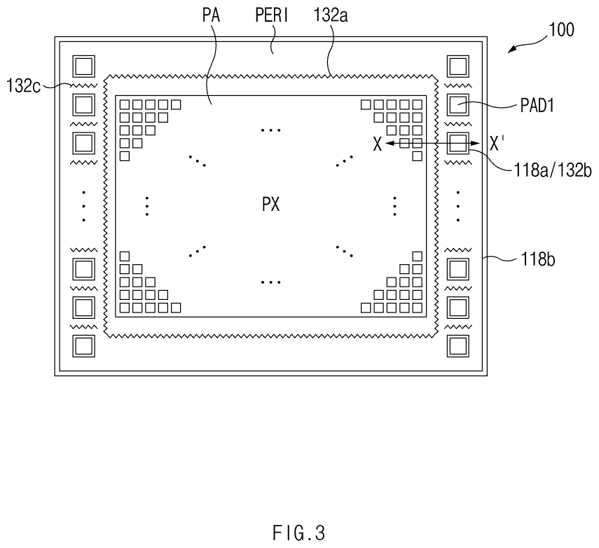

FIG. 3 is a plan view illustrating an example of a planar arrangement of the first stacked structure in the image sensing device shown in FIG. 2 based on some implementations of the disclosed technology.

Referring to FIG. 3, the first stacked structure 100 may include a pixel area (PA) in which the pixel array 10 of FIG. 1 is formed, and a peripheral area (PERI) located outside the pixel area (PA). The peripheral area (PERI) may be formed to surround the pixel area (PA), and may include first pad regions (PAD1). The first pad region (PAD1) may include a pad open region for exposing the electrode pad.

The pixel area (PA) may include a plurality of unit pixels (PXs) arranged in a plurality of rows and a plurality of columns. The pixel area (PA) may include a photoelectric conversion region, a color filter, a lens layer, and pixel transistors.

Substrate isolation structures (118a, 118b) may be formed in the peripheral area (PERI) to reduce or minimize signal interference between pad regions and prevent an electrical signal from being introduced from the outside. For example, the substrate isolation structures (118a, 118b) may include first substrate isolation structures 118a that surround each of the first pad regions (PAD1) to prevent signal interference between the pad regions; and at least one second substrate isolation structure 118b that is formed at an edge (e.g., the outermost edge) of the peripheral area (PERI) to surround (e.g., entirely surround) both the pixel area (PA) and the peripheral area (PERI) to prevent electrical signals from being introduced from the outside. The substrate isolation structures (118a, 118b) may be formed to have the same structure, and may be formed to penetrate the substrate within the first stacked structure 100. A light blocking layer including a metal layer may be formed over the substrate isolation structures (118a, 118b).

In the peripheral area (PERI) of the first stacked structure 100, adhesion-enhancing structures (132a, 132b, 132c) may be formed to provide enhanced adhesion or engagement of different layers in the first stacked structure 100, including, for example, enhancement of the lens layer and preventing peeling of the lens layer. For example, the adhesion-enhancing structures (132a, 132b, 132c) may include: a first adhesion-enhancing structure 132a formed between the pixel area (PA) and the first pad regions (PAD1) in the peripheral area (PERI); second adhesion-enhancing structures 132b formed over the substrate isolation structure 118a to surround the first pad regions (PAD1); and third adhesion-enhancing structures 132c formed between the first pad regions (PAD1). The adhesion-enhancing structures (132a, 132b, 132c) may be formed to have the same structure. In addition, an adhesion-enhancing structure may also be formed over the second substrate isolation structure 118b. In some implementations, each of the adhesion-enhancing structures may include a plurality of protrusions and recesses to increase contact force by enlarging the contact area with another material layer. In some implementations, each of the adhesion-enhancing structures may include a roughened or textured surface that can improve adhesion. Here, the roughened or textured surface includes all forms of uneven surface.

All of the adhesion-enhancing structures (132a, 132b, 132c) may be formed in the first stacked structure 100, or only some of the adhesion-enhancing structures (132a, 132b, 132c) may be selectively formed in the first stacked structure 100. Such adhesion-enhancing structures will be described in more detail later.

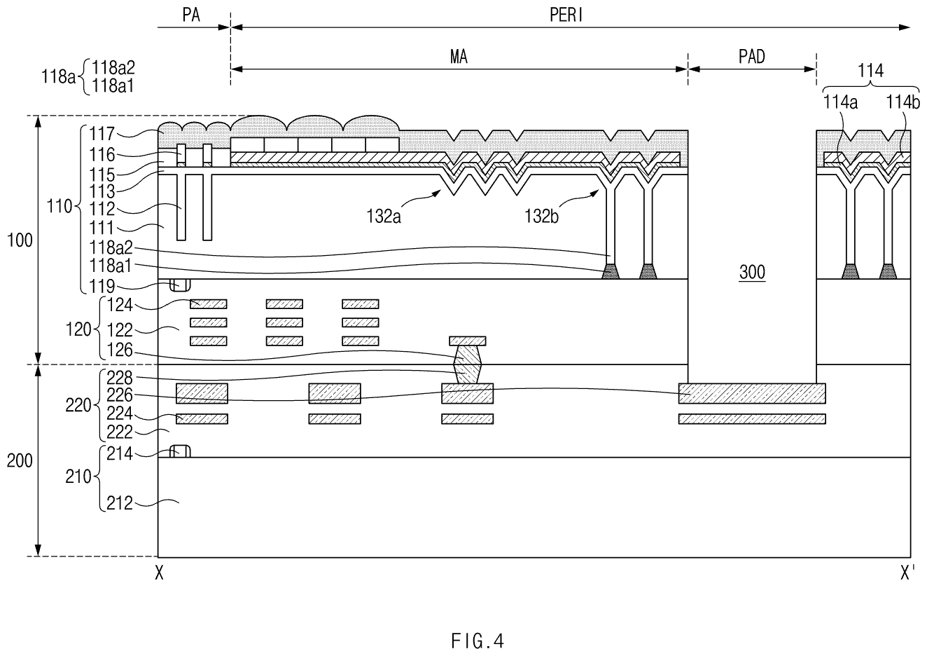

FIG. 4 is a cross-sectional view illustrating an example of a cross-section taken along the line X-X′ of FIG. 3 in the stacked structure shown in FIG. 2 based on some implementations of the disclosed technology.

Referring to FIG. 4, the image sensing device may include a first stacked structure 100, a second stacked structure 200, and a pad open region 300.

The first substrate layer 110 may include a first substrate 111, a pixel isolation structure 112, a planarization layer 113, a light blocking layer 114, color filters 115, a grid structure 116, a lens layer 117, substrate isolation structures 118a, and a pixel transistor 119.

The first substrate 111 may include a pixel area (PA) and a peripheral area (PERI), and the peripheral area (PERI) may include a pad region (PAD) and a middle area (MA). The middle area (MA) may represent a region between the pixel area (PA) and the pad regions (PAD) in the peripheral area (PERI).

The first substrate 111 may include a first front surface and a first back surface facing or opposite to the first front surface. The first back surface of the first substrate 111 may be a light reception surface upon which light is incident, and may be formed to have a planarization layer 113, a light blocking layer 114, color filters 115, a grid structure 116, and a lens layer 117. The first front surface of the first substrate 111 may be formed to have pixel transistors 119, and may be in contact with the first interconnect layer 120. That is, the image sensing device may refer to a backside illuminated (BSI) image sensing device.

The first substrate 111 may include a first adhesion-enhancing structure 132a formed in the middle area (MA) and a plurality of second adhesion-enhancing structures 132b formed over the substrate isolation structures 118a. In some implementations, the adhesion-enhancing structures (132a, 132b) may include a plurality of trenches formed by etching the first back surface of the first substrate 111. In an example, a cross-section of each of the adhesion-enhancing structures (132a, 132b) has a triangular shape to increase contact force by enlarging the contact area with another material layer. The adhesion-enhancing structures (132a, 132b) may prevent peeling of the lens layer 117 effectively by increasing a contact area of the bottom surface of the lens layer 117. The first adhesion-enhancing structure 132a may be formed in the middle area (MA) between the pixel area (PA) and the pad region (PAD) to surround the pixel area (PA), as shown in FIG. 3. The second adhesion-enhancing structure 132b may be formed over the substrate isolation structures 118a. For convenience of description, only the first and second adhesion-enhancing structures (132a, 132b) are illustrated in FIG. 4, but as shown in FIG. 3, the first substrate 111 may further include third adhesion-enhancing structures 132c disposed between the pad regions (PAD).

In the first substrate 111, the pad region (PAD) may refer to a pad open region 300 through which the first substrate 111 passes or extends.

The first substrate 111 may include a semiconductor substrate. For example, the first substrate 111 may be a bulk-silicon substrate or a silicon-on-insulator (SOI) substrate. Alternatively, the first substrate 111 may be formed of an epitaxial layer formed over a base substrate.

The pixel isolation structure 112 may separate (isolate) photoelectric conversion regions of adjacent unit pixels (PX) from each other within the first substrate 111. For example, photoelectric conversion regions (e.g., photodiodes (PDs)) may be formed to correspond to the unit pixels (PXs) in regions defined by the pixel isolation structures 112 within the first substrate 111. The pixel isolation structure 112 may include a trench isolation structure in which an insulation material is buried in a trench etched to a predetermined depth in the first substrate 111. For example, the pixel isolation structure 112 may have a deep trench isolation (DTI) structure in which oxide layers (e.g., Al₂O₃, HfO₂, and high aspect ratio process (HARP) oxide layers) and nitride layer(s) are buried to be stacked in the trench.

The planarization layer 113 may be formed over the first back surface of the first substrate 111. The planarization layer 113 may be formed to entirely cover the first back surface of the first substrate 111. The planarization layer 113 may be formed of the same materials as the pixel isolation structure 112. For example, the planarization layer 113 may be formed together with the insulation materials formed in the pixel isolation structure 112. The planarization layer 113 may be formed along a surface of the plurality of protrusions and recesses of the adhesion-enhancing structures (132a, 132b) in the area where the adhesion-enhancing structures (132a, 132b) are formed.

The light blocking layer 114 may be formed over the planarization layer 113 in the peripheral area (PERI) to prevent incident light from being introduced into the first substrate 111 of the peripheral area (PERI). The light blocking layer 114 may extend from a boundary area between the pixel area (PA) and the peripheral area (PERI) to the edge (e.g., the outermost edge) of the peripheral area (PERI). The light blocking layer 114 may not be formed in the pad regions (PAD). For example, the light blocking layer 114 may be formed to entirely cover the peripheral area (PERI) except for the pad regions (PAD) and some areas adjacent to the pad regions (PAD).

The light blocking layer 114 may include a metal. For example, the light blocking layer 114 may include a structure in which a barrier metal layer 114a and an additional metal layer 114b are stacked. The barrier metal layer 114a may include titanium (Ti), titanium nitride (TiN), tantalum (Ta), and tantalum nitride (TaN), and the additional metal layer 114b may include tungsten (W).

Since each of the substrate isolation structures (118a, 118b) is formed as a thin and deep structure, it may be easily damaged by external impact and can serve as a path for moisture penetration. In addition, since the substrate isolation structures (118a, 118b) are formed to penetrate the first substrate 111, any moisture entering through the damaged substrate isolation structures (118a, 118b) may easily reach the interconnect layer in which metal interconnects are formed. In an embodiment of the disclosed technology, the light blocking layer 114 covers the substrate isolation structures (118a, 118b) to protect the substrate isolation structures (118a, 118b) from external impact and to more effectively prevent moisture from penetrating through the substrate isolation structures (118a, 118b).

The light blocking layer 114 may be formed to include a plurality of protrusions and recesses, like the adhesion-enhancing structure, along the planarization layer 113 in the area where the adhesion-enhancing structures (132a, 132b) are formed.

The color filters 115 may selectively transmit visible light from the incident light. The color filters 115 may include red, green, or blue color filters (R, G, B) arranged in a Bayer pattern. The color filters 115 may be formed over the planarization layer 113 in the pixel area (PA), and may be formed over the light blocking layer 114 in the middle area (MA).

The grid structure 116 may be disposed between the color filters 115 to prevent crosstalk of incident light between adjacent color filters 115. The grid structure 116 may include a barrier metal layer and an air layer. The barrier metal layer of the grid structure 116 may be formed together with the barrier metal layer 114a of the light blocking layer 114 through the same process.

The lens layer 117 may converge incident light onto the photoelectric conversion regions of the unit pixels. The lens layer 117 may include an over-coating layer; and microlenses formed over the over-coating layer and formed in a hemispherical shape. A lens capping layer for protecting the lens layer 117 and preventing a flare phenomenon occurring in the lens layer 117 may be formed over the lens layer 117.

The lens layer 117 may be formed to extend to the peripheral area (PERI). For example, a lens material of the lens layer 117 may extend to the peripheral area (PERI) to entirely cover the peripheral area (PERI) except for the pad regions (PAD). The lens layer 117 may be formed between the light blocking layer 114 and the pad open region 300 to prevent the light blocking layer 114 from being exposed to the outside.

The substrate isolation structures 118a may be formed to surround the pad regions (PAD) so that the pad regions (PAD) are isolated from each other in the peripheral area (PERI). The substrate isolation structures 118a may be formed to surround each of the pad regions (PAD) in a double manner. As described above, the substrate isolation structures 118a may be formed to surround each of the pad regions (PAD), thereby preventing signal interference between the pad regions (PAD).

Although FIG. 4 shows only the first substrate isolation structures 118a surrounding the pad regions (PAD) for convenience of description, other implementations are also possible, and it should be noted that the second substrate isolation structure 118b may be formed at the outermost edge of the first substrate 111 to entirely surround the pixel area (PA) and the peripheral area (PERI) as shown in FIG. 3. The adhesion-enhancing structure and the light blocking layer 114 may also be formed over the second substrate isolation structure 118b.

The substrate isolation structures 118a may be formed to penetrate the first substrate 111. The substrate isolation structures 118a may include a lower substrate isolation structure 118ₐ1 and an upper substrate isolation structure 118ₐ2 that are vertically stacked. The lower substrate isolation structure 118ₐ1 may include a shallow trench isolation (STI) structure in which an insulation material is buried in a trench etched to a predetermined depth from the first front surface of the first substrate 111. The upper substrate isolation structure 118a2 may include a deep trench isolation (DTI) structure in which insulation materials are buried in a trench etched from the second adhesion-enhancing structure 132b to the lower substrate isolation structure 118a1. The insulation materials of the upper substrate isolation structure 118a2 may be formed together when the insulation materials of the pixel isolation structure 112 are formed.

The pixel transistors 119 may be formed over the first front surface of the first substrate 111 to be electrically connected to the first metal interconnects 124 of the first interconnect layer 120. The pixel transistors 119 may be formed to correspond to the unit pixels (PXs) in the pixel area (PA). The pixel transistors 119 may generate pixel signals corresponding to the magnitude of photocharges generated by the photoelectric conversion region of the corresponding unit pixel (PX), and may output the pixel signals through the first metal interconnects 124. The pixel transistors 119 may include a transfer transistor, a reset transistor, a source follower transistor, and a selection transistor.

The first interconnect layer 120 may be formed under the first front surface to contact the first front surface of the first substrate 111. The first interconnect layer 120 may be formed to contact the second interconnect layer 220 of the second stacked structure 200. The first interconnect layer 120 may include a first interlayer insulation layer 122, first metal interconnects 124, and a first bonding structure 126.

The first interlayer insulation layer 122 may include insulation materials that are formed not only between the pixel transistors 119 and the first metal interconnects 124 but also between the first metal interconnects 124. For example, the first interlayer insulation layer 122 may include at least one of silicon oxide, silicon nitride, and silicon oxynitride.

The first metal interconnects 124 may be formed within the first interlayer insulation layer 122 and may be electrically connected to the pixel transistors 119. Some of the metal interconnects included in the lowermost layer of the first metal interconnects 124 may be connected to a first bonding structure 126.

The first bonding structure 126 may be directly connected to the second bonding structure 228 of the second interconnect layer 220. That is, the first stacked structure 100 and the second stacked structure 200 may be electrically connected to each other by a hybrid bonding method (or a direct bonding method) using the first bonding structure 126 and the second bonding structure 228.

The first pad region (PAD1) of the first stacked structure 100 may be formed as a pad open region 300 for exposing the electrode pad 226 formed in the second stacked structure 200.

The second stacked structure 200 may include a second substrate layer 210 and a second interconnect layer 220.

The second substrate layer 210 may include a second substrate 212 and logic transistors 214.

The second substrate 212 may include a logic area (LA) and a second pad region (PAD2) located outside the logic area (LA). The second substrate 212 may include a second front surface and a second back surface facing or opposite to the second front surface. The second front surface may be a surface that contacts the second interconnect layer 220, and a plurality of logic transistors 214 may be formed over the second front surface. The second substrate 212 may include a semiconductor substrate such as the first substrate 111.

The logic transistors 214 may be formed over the second front surface of the second substrate 212 to be connected to second metal interconnects 224. The logic transistors 214 may generate control signals for controlling the operation of the unit pixels (PX), and may generate an image by processing pixel signals output from the unit pixels (PX). For example, the logic transistors 214 may include a plurality of transistors that constitutes the row driver 20, the CDS 30, the ADC 40, the output buffer 50, the column driver 60, and the timing controller 70 shown in FIG. 1. The logic transistors 214 may be formed in the logic area (LA) of the second substrate 212. The logic transistors 214 may be electrically connected to an external device through the electrode pad 226.

The second interconnect layer 220 may be formed over the second front surface to contact the second front surface of the second substrate 212, and may contact the first interconnect layer 120 of the first stacked structure 100. The second interconnect layer 220 may include the second interlayer insulation layer 222, the second metal interconnects 224, the electrode pad 226, and the second bonding structure 228.

The second interlayer insulation layer 222 may include insulation materials that are formed not only between the logic transistors 214 and the second metal interconnects 224 but also between the second metal interconnects 224. For example, the second interlayer insulation layer 222 may include at least one of silicon oxide, silicon nitride, and silicon oxynitride.

The second metal interconnects 224 may be formed in the second interlayer insulation layer 222, and may be electrically connected to the logic transistors 214. Some of the metal interconnects included in the uppermost layer of the second metal interconnects 224 may be connected to the second bonding structure 228, and some other of the metal interconnects included in the uppermost layer of the second metal interconnects 224 may be used as the electrode pad 226. The metal interconnects included in the uppermost layer of the second metal interconnects 224 may be formed to be thicker than the other metal interconnects, and may include aluminum (Al).

The electrode pad 226 may be disposed in the second interlayer insulation layer 222 within the second pad region (PAD2), and a top surface of the electrode pad 226 may be exposed by the pad open region 300. The top surface of the exposed electrode pad 226 may be directly connected to the bonding wire through the pad open region 300. The electrode pad 226 may be a part of the metal interconnects included in the uppermost layer among the second metal interconnects 224.

The second bonding structure 228 may be directly connected to the first bonding structure 126 of the first interconnect layer 120.

The pad open region 300 may include an empty space formed by etching the first stacked structure 100 and the second stacked structure 200 to expose the electrode pad 226. For example, the pad open region 300 may be formed by the first stacked structure 100 penetrating the first pad region (PAD1), and may also be formed by the second interlayer insulation layer 222 that is partially etched to the top surface of the electrode pad 226 in the second pad region (PAD2). The bonding wire may be formed within the pad open region 300.

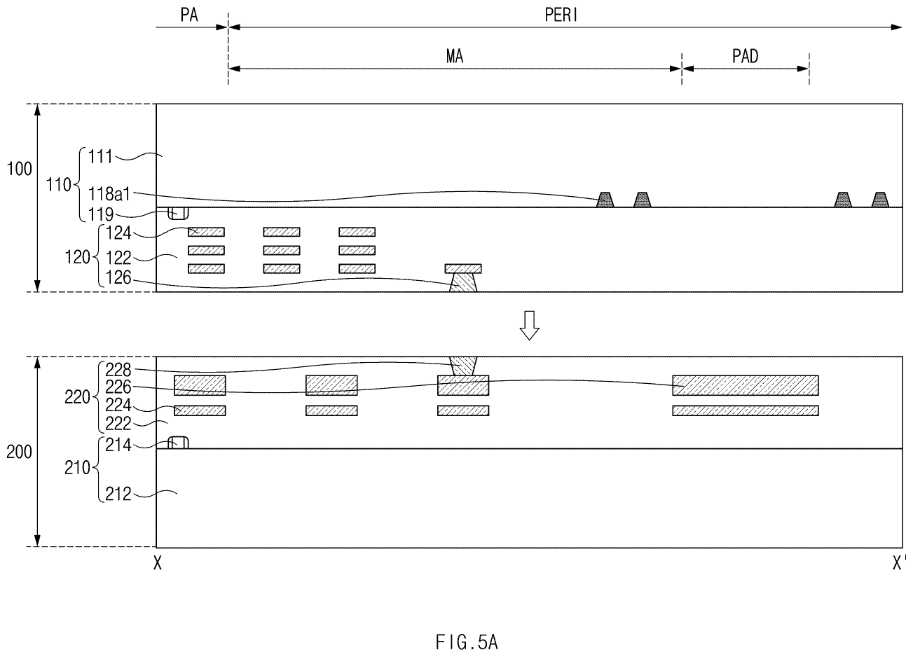

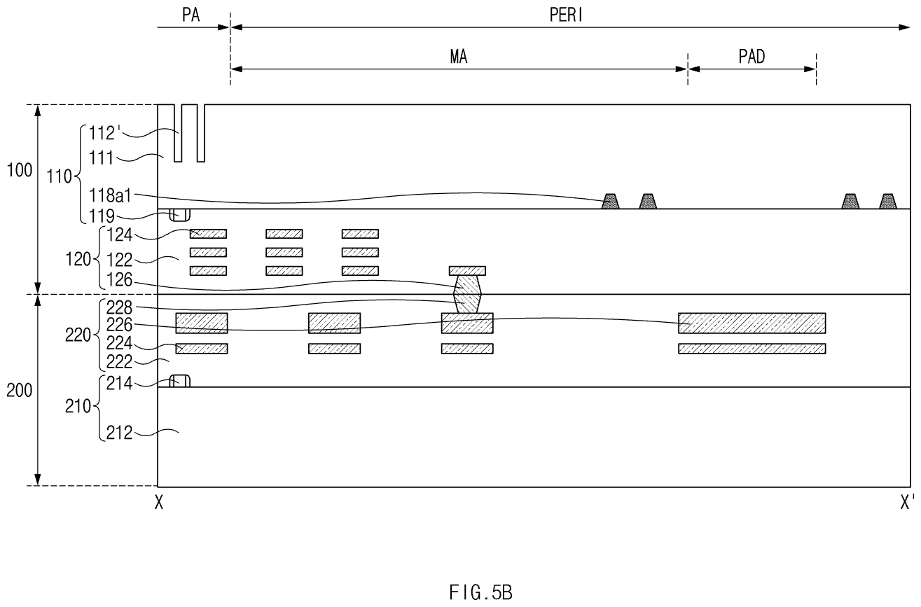

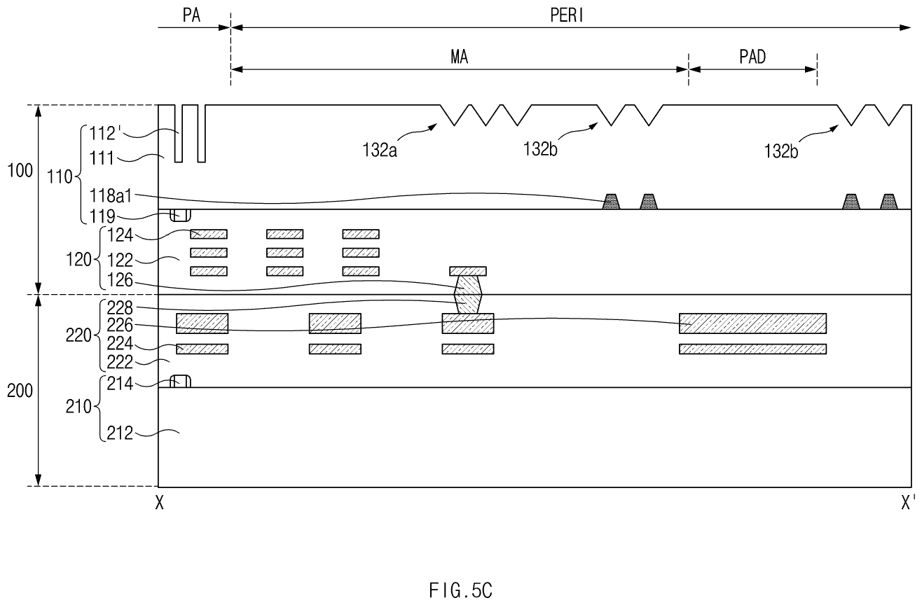

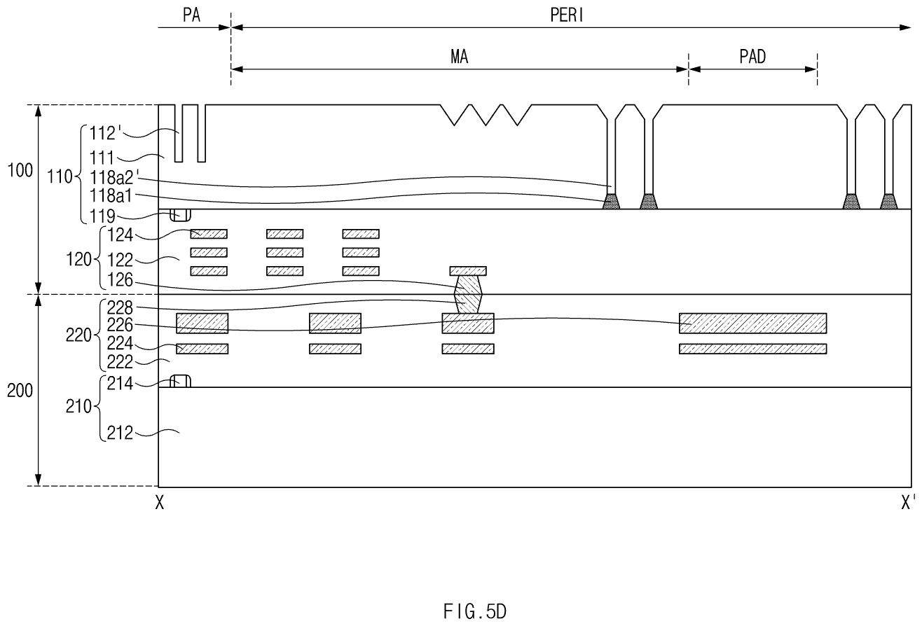

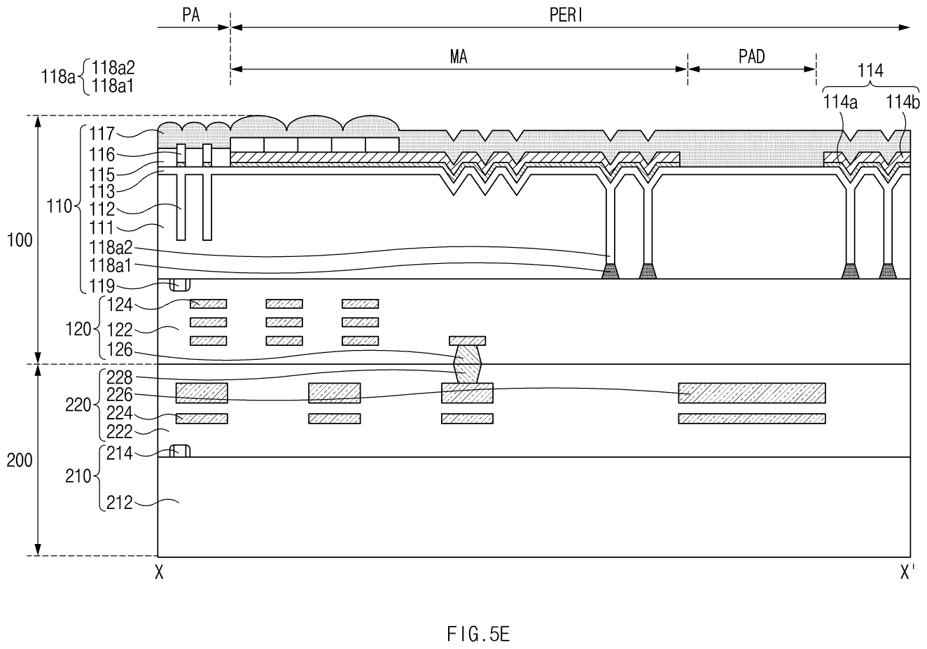

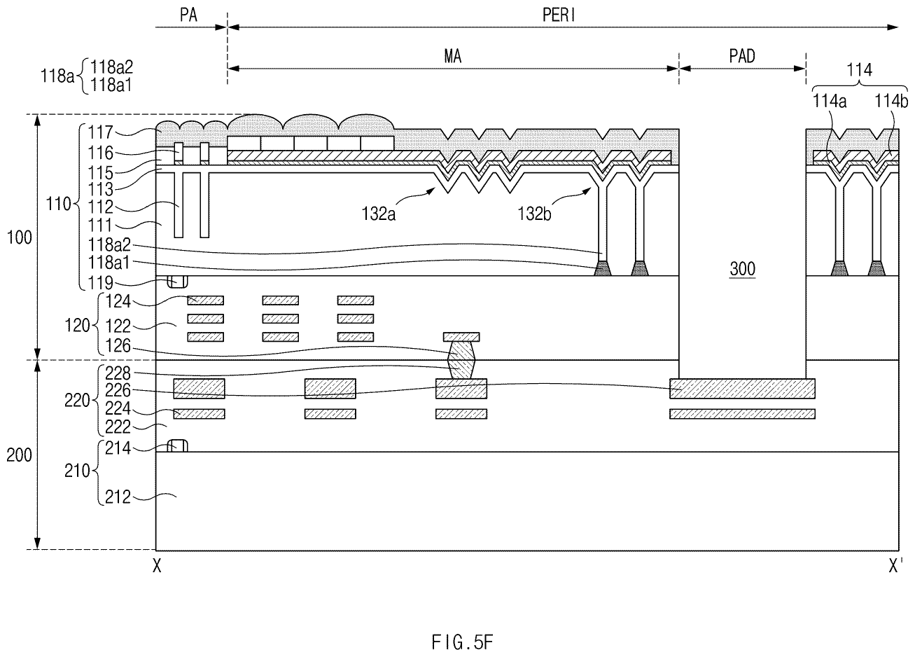

FIGS. 5A to 5F are cross-sectional views illustrating examples of a method for forming the structure of FIG. 4 based on some implementations of the disclosed technology.

Referring to FIG. 5A, pixel transistors 119 and lower substrate isolation structures 118a1 may be formed over the first front surface of the first substrate 111. The lower substrate isolation structures 118a1 may be formed in a shallow trench isolation (STI) structure, and may be formed together with a device isolation layer for isolating the pixel transistors 119 from each other within the pixel area (PA).

Subsequently, a first interconnect layer 120 including a first interlayer insulation layer 122, first metal interconnects 124, and a first bonding structure 126 may be formed over the first front surface.

In addition, after logic transistors 214 are formed over the second front surface of the second substrate 212, a second interconnect layer 220 including a second interlayer insulation layer 222, second metal interconnects 224, an electrode pad 226, and a second bonding structure 228 may be formed over the second front surface.

Thereafter, the first stacked structure 100 and the second stacked structure 200 may be attached so that the first bonding structure 126 and the second bonding structure 228 are directly bonded to each other.

Referring to FIG. 5B, the first substrate 111 of the pixel area (PA) may be etched from the first back surface to a predetermined depth, resulting in formation of trenches 112′ for forming the pixel isolation structures 112.

Referring to FIG. 5C, since the first substrate 111 is etched to a predetermined depth from the first back surface in each of the middle area (MA) and another area in which the substrate isolation structures 118a are to be formed, the adhesion-enhancing structures (132a, 132b) for preventing peeling of the lens layer may be formed. For example, the adhesion-enhancing structures (132a, 132b) may include a plurality of trenches etched so that a cross-section of each trench has a triangular shape. In some implementations, the first adhesion-enhancing structure 132a may be formed to surround the pixel area (PA) within the middle area (MA), and the second adhesion-enhancing structures 132b may be formed to surround each of the first pad regions (PAD1). In addition, as shown in FIG. 3, third adhesion-enhancing structures 132c may also be formed between adjacent first pad regions (PAD1).

Referring to FIG. 5D, the bottom surface of a second adhesion-enhancing structure 132b may be etched to form trenches 118a2′ for forming upper substrate isolation structures 118a2. For example, the trenches 118a2′ may be formed by etching the first substrate 111 until the lower substrate isolation structures 118a1 are exposed.

Referring to FIG. 5E, insulation materials are formed to fill the trenches (112′ in FIGS. 5B-5D, 118a2′ in FIG. 5D) so that the pixel isolation structures 112 and the upper substrate isolation structures 118a2 can be formed. For example, the pixel isolation structures 112 and the upper substrate isolation structures 118a2 may be formed by stacking a nitride layer and oxide layers (e.g., Al₂O₃, HfO₂, HARP oxide layers) and a nitride layer to fill the trenches (112′ in FIGS. 5B-5D, 118a2′ in FIG. 5D). In some implementations, the corresponding insulation materials may also be stacked over the first back surface of the first substrate 111 in which the adhesion-enhancing structures (132a, 132b) are formed, resulting in formation of a planarization layer 113.

Since the planarization layer 113 is formed to have an overall uniform thickness, the planarization layer 113 may include one or more protrusions and recesses formed in a region where the adhesion-enhancing structures (132a, 132b) are formed, within the first substrate 111.

Subsequently, the light blocking layer 114 and the grid structure 116 may be formed over the planarization layer 113.

For example, after a barrier metal layer and an additional metal layer are sequentially formed over the planarization layer 113, the barrier metal layer and the additional metal layer are patterned in a manner that the barrier metal layer and the additional metal layer disposed in the pad region (PAD) of the peripheral area (PERI) are removed and the barrier metal layer and the additional metal layer disposed in the pixel region (PA) are selectively remained in the region where the grid structure 116 is to be formed. As a result, the light blocking layer 114 can be formed. When the barrier metal layer and the additional metal layer are removed from the pad region (PAD), the barrier metal layer and the additional metal layer can be removed over a wider area than the pad region (PAD).

Subsequently, after the additional metal layer is removed so that only the barrier metal layer remains in the region where the grid structure 116 is to be formed, the air layer is formed over the barrier metal layer, resulting in formation of the grid structures 116.

The light blocking layer 114 may be formed to have an overall uniform thickness, so that the light blocking layer 114 may also include the protrusions and recesses formed in the region where the adhesion-enhancing structures (132a, 132b) are formed in the first substrate 111.

Subsequently, the color filters 115 may be formed in the pixel area (PA) and the middle area (MA). In the middle area (MA), the color filters 115 may be formed only in some areas adjacent to the pixel area (PA).

Then, a lens layer 117 may be formed in the pixel area (PA) and the peripheral area (PERI). In some implementations, since the lens layer 117 is also formed over the light blocking layer 114 having the protrusions and recesses, a contact area between the lens layer 117 and the light blocking layer 114 may increase compared to the case where the protrusions and recesses are not formed over the light blocking layer 114. As a result, it is possible to more effectively prevent tearing of the lens layer 117 in a subsequent process.

Referring to FIG. 5F, the lens layer 117, the planarization layer 113, the first substrate 111, the first interlayer insulation layer 122, and the second interlayer insulation layer 222 of the pad region (PAD) may be sequentially etched until the electrode pad 226 is exposed, thereby forming a pad open region 300.

The pad open region 300 may be formed to have a smaller size (e.g. width) than the area from which the light blocking layer 114 is removed, so that a side surface of the light blocking layer 114 may be covered and protected by the lens layer 117 without being exposed by the pad open region 300.

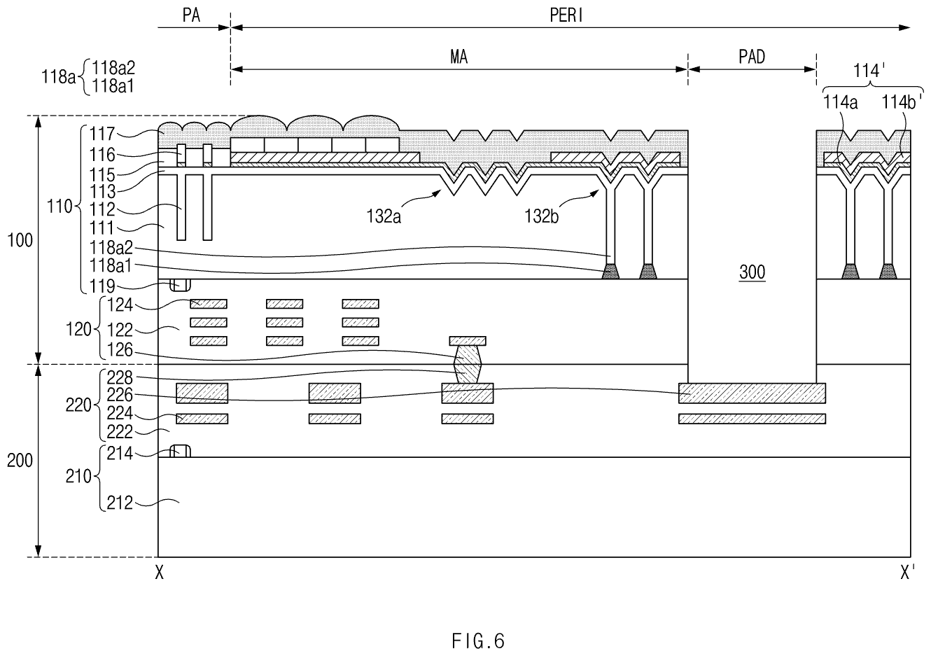

FIG. 6 is a cross-sectional view illustrating an example structure of the image sensing device based on some other implementations of the disclosed technology.

Referring to FIG. 6, the light blocking layer 114′ may include a barrier metal layer 114a and an additional metal layer 114b′.

Compared to the light blocking layer 114 of FIG. 4, the light blocking layer 114′ of FIG. 6 is different in structure of the additional metal layer 114b′. For example, the light blocking layer 114′ may be formed as a monolayer (or single layer) structure of the barrier metal layer 114a without the additional metal layer 114b′ over the first adhesion-enhancing structure 132a, and may be formed as a multilayer structure (i.e., a stacked layer structure) of the barrier metal layer 114a and the additional metal layer 114b′ in other areas except for the monolayer structure. When adhesion-enhancing structures (132c of FIG. 3) are formed between the pad regions (PAD), the light blocking layer 114′ may also be formed as a monolayer structure of the barrier metal layer 114a even in the corresponding adhesion-enhancing structures 132c. The additional metal layer 114b′ formed over the adhesion-enhancing structures (132a, 132c) may be removed simultaneously with the additional metal layer 114b′ when the additional metal layer 114b′ is removed to form the grid structure 116.

In some implementations, in the second adhesion-enhancing structures 132b formed over the first substrate isolation structures 118a, the light blocking layer 114′ is formed as a multilayer structure of the barrier metal layer 114a and the additional metal layer 114b′, thereby protecting the first substrate isolation structures 118a.

In the other adhesion-enhancing structures (132a, 132c) except for the second adhesion-enhancing structures 132b, the light blocking layer 114′ is formed so as not to include the additional metal layer 114b′, so that the contact area of the lens layer 117 is further increased in size as compared to the structure of FIG. 4, thereby more effectively preventing peeling of the lens layer 117.

When adhesion-enhancing structures (132c in FIG. 3) are formed between the pad regions (PAD), the light blocking layer 114′ formed in the adhesion-enhancing structures 132c may also not include the additional metal layer 114b′.

Although FIG. 6 shows the example case in which the light blocking layer 114′ formed in the first adhesion-enhancing structure 132a includes only the barrier metal layer 114a, other implementations are also possible, and it should be noted that the barrier metal layer 114a may not be formed in the first adhesion-enhancing structure 132a. In other words, the light blocking layer 114′ may not be formed over the first adhesion-enhancing structure 132a. Similarly, the light blocking layer 114′ may not be formed over the adhesion-enhancing structures between the pad regions (PAD).

In FIG. 6, the remaining structures other than the light blocking layer 114′ may be the same as in FIG. 4, and as such redundant description thereof will herein be omitted for brevity.

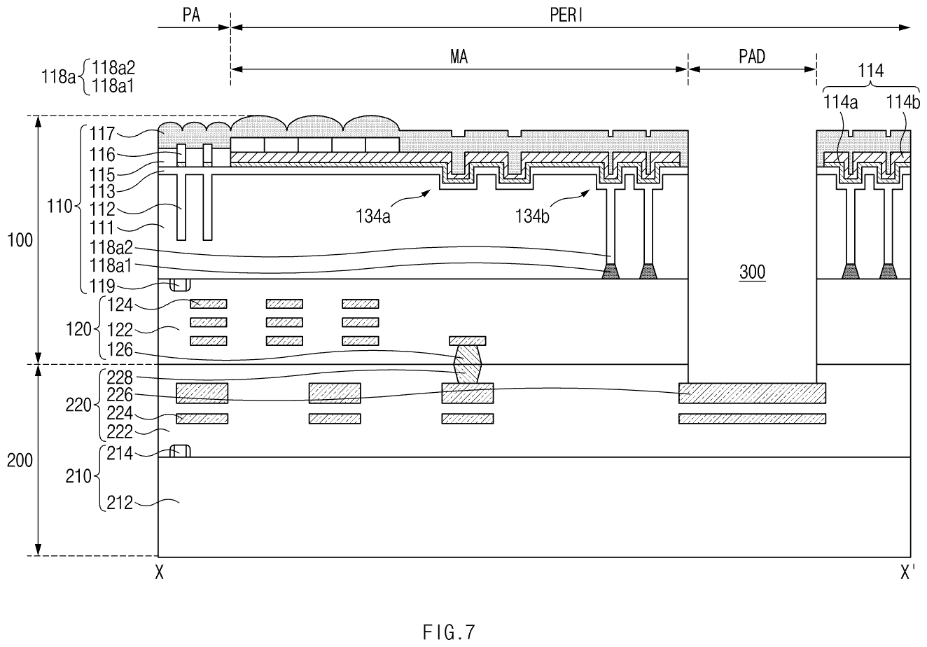

FIG. 7 is a cross-sectional view illustrating an example structure of the image sensing device based on some other implementations of the disclosed technology.

Referring to FIG. 7, the first substrate 111 may include adhesion-enhancing structures (134a, 134b) formed in the middle area (MA) and the first substrate isolation structures 118a. Unlike the adhesion-enhancing structures (132a, 132b) shown in FIG. 4, the adhesion-enhancing structures (134a, 134b) shown in FIG. 7 may include a plurality of trenches formed by etching the first substrate 111 so that a cross-section of each trench has a rectangular shape. The adhesion-enhancing structures (134a, 134b) of FIG. 7 may be formed at the same positions as in the adhesion-enhancing structures (132a, 132b) of FIG. 4.

Although FIG. 7 shows only the adhesion-enhancing structures (134a, 134b) for convenience of description, other implementations are also possible, and it should be noted that the adhesion-enhancing structures each having a square cross-sectional structure of FIG. 7 may also be formed in the region between the pad regions (PAD) in the same manner as in the adhesion-enhancing structures 132c of FIG. 3.

The structures except for the adhesion-enhancing structures (134a, 134b) in FIG. 7 may be the same as those in FIG. 4, and as such redundant description thereof will herein be omitted for brevity.

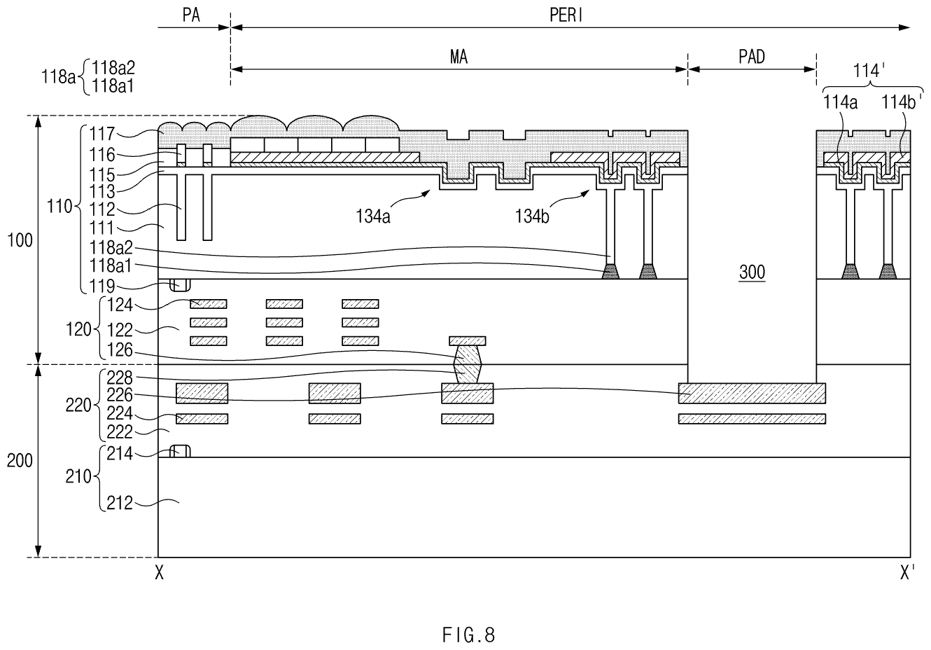

FIG. 8 is a cross-sectional view illustrating an example structure of the image sensing device based on some other implementations of the disclosed technology.

Referring to FIG. 8, the light blocking layer 114′ may include a barrier metal layer 114a and an additional metal layer 114b′.

Compared to the light blocking layer 114 of FIG. 7, the light blocking layer 114′ of FIG. 8 is different in structure of the additional metal layer 114b′. For example, in the adhesion-enhancing structure 134a formed in the middle area (MA), the light blocking layer 114′ may include only the barrier metal layer 114a without the additional metal layer 114b′. In addition, when adhesion-enhancing structures of FIG. 7 are formed between pad regions (PAD) in the same manner as in FIG. 3, the light blocking layer 114′ may include only the barrier metal layer 114a even in the corresponding adhesion-enhancing structures.

Although FIG. 8 shows the example case in which the light blocking layer 114′ formed in the adhesion-enhancing structure 134a includes only the barrier metal layer 114a, other implementations are also possible, and it should be noted that the barrier metal layer 114a may not be formed in the adhesion-enhancing structure 134a. In other words, the light blocking layer 114′ may not be formed over the first adhesion-enhancing structure 134a. Similarly, the light blocking layer 114′ may not be formed over the adhesion-enhancing structures between the pad regions (PAD).

In FIG. 8, the remaining structures other than the light blocking layer 114′ may be the same as in FIG. 7, and as such redundant description thereof will herein be omitted for brevity.

Although the above-described embodiments have disclosed the example cases in which the adhesion-enhancing structures are formed in all of the middle area (MA), the substrate isolation structure (118a) region, and the region disposed between the pad regions (PAD), other implementations are also possible, and it should be noted that the adhesion-enhancing structures may be selectively formed in the corresponding regions. For example, the adhesion-enhancing structures may be formed only in the substrate isolation structure (118a) region. Alternatively, the adhesion-enhancing structures may be formed only in the region between the middle area (MA) and the pad regions (PAD).

Regardless of the presence or absence of the adhesion-enhancing structures, the light blocking layers (114, 114′) may be formed to include the barrier metal layer 114a and the additional metal layer 114b or 114b′ over the substrate isolation structures (118a, 118b) region.

As described above, the image sensing device based on some implementations of the disclosed technology may prevent damage to substrate isolation structures and peeling of the lens layer, thereby improving the operational characteristics of the image sensing device.

The disclosed technology may provide a variety of effects, which can be directly or indirectly recognized through the above-mentioned embodiments and other embodiments.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a substrate including a pixel area configured to include image sensing pixels and a peripheral area located outside the pixel area, wherein the peripheral area includes pad regions and a first adhesion-enhancing structure, and the first adhesion-enhancing structure is located between the pixel area and the pad regions and includes a plurality of protrusions and recesses;
a plurality of first substrate isolation structures disposed in the substrate and surrounding each of the pad regions; and
a light blocking layer disposed over the substrate and configured to cover the first adhesion-enhancing structure and the first substrate isolation structures.

2. The image sensing device according to claim 1, wherein:
the light blocking layer is configured to cover the peripheral area without covering the pad regions.

3. The image sensing device according to claim 1, wherein:
the light blocking layer is formed along a surface of the plurality of protrusions and recesses of the first adhesion-enhancing structure.

4. The image sensing device according to claim 1, wherein the light blocking layer includes:
a barrier metal layer; and
an additional metal layer formed over the barrier metal layer.

5. The image sensing device according to claim 4, wherein the light blocking layer includes:
a monolayer structure including the barrier metal layer disposed over the first adhesion-enhancing structure; and
a multilayer structure including both the barrier metal layer and the additional metal layer disposed over the first substrate isolation structures.

6. The image sensing device according to claim 1, wherein the substrate further includes:
a plurality of second adhesion-enhancing structures disposed over the first substrate isolation structures and configured to surround each of the pad regions, each of the plurality of second adhesion-enhancing structures including a plurality of protrusions and recesses.

7. The image sensing device according to claim 6, wherein the light blocking layer includes:
a multilayer structure that includes both a barrier metal layer and an additional metal layer disposed over the second adhesion-enhancing structures.

8. The image sensing device according to claim 7, wherein:
the light blocking layer is formed along a surface of the plurality of protrusions and recesses of the second adhesion-enhancing structures.

9. The image sensing device according to claim 6, wherein the substrate further includes:
a plurality of third adhesion-enhancing structures disposed between the pad regions and including a plurality of protrusions and recesses.

10. The image sensing device according to claim 9, wherein:
the light blocking layer includes a monolayer structure that includes a barrier metal layer disposed over the third adhesion-enhancing structures.

11. The image sensing device according to claim 1, further comprising:
a second substrate isolation structure disposed in the substrate at an edge of the substrate and configured to surround the pixel area and the peripheral area.

12. The image sensing device according to claim 11, wherein:
the light blocking layer extends to cover the second substrate isolation structure.

13. The image sensing device according to claim 1, wherein each of the pad regions includes:
a pad open region through which the substrate passes.

14. An image sensing device comprising:
a first stacked structure including a pixel area and a plurality of first pad regions, wherein the pixel area includes image sensing pixels, and the plurality of first pad regions are located outside the pixel area; and
a second stacked structure stacked electrically connected to the first stacked structure, wherein the second stacked structure includes a logic area configured to include logic circuits and a plurality of second pad regions located outside the logic area, and each second pad region includes an electrode pad,
wherein the first stacked structure includes:
a substrate configured to include pad open regions formed in the first pad regions and a first adhesion-enhancing structure disposed between the pixel area and the pad open regions and including a plurality of protrusions and recesses;
substrate isolation structures disposed to penetrate the substrate and configured to surround each of the first pad regions; and
a light blocking layer disposed over the substrate and configured to cover the first adhesion-enhancing structure and the substrate isolation structures.

15. The image sensing device according to claim 14, wherein:
the light blocking layer is formed along a surface of the plurality of protrusions and recesses of the first adhesion-enhancing structure.

16. The image sensing device according to claim 14, wherein the light blocking layer includes:
a barrier metal layer; and
an additional metal layer formed over the barrier metal layer.

17. The image sensing device according to claim 16, wherein the light blocking layer includes:
a monolayer structure including the barrier metal layer disposed over the first adhesion-enhancing structure; and
a multilayer structure including both the barrier metal layer and the additional metal layer disposed over the substrate isolation structures.

18. The image sensing device according to claim 14, wherein the substrate further includes:
a plurality of second adhesion-enhancing structures disposed over the substrate isolation structures and configured to surround each of the first pad regions.

19. The image sensing device according to claim 18, wherein:
the light blocking layer is formed along the second adhesion-enhancing structure over a surface of the plurality of protrusions and recesses of the second adhesion-enhancing structure.

20. The image sensing device according to claim 18, wherein the substrate further includes:
a plurality of third adhesion-enhancing structures disposed between the first pad regions and including a plurality of protrusions and recesses.
